(19) United States
(12) Patent Application Publication
(10) Pub. No.: US 2010/0084733 A1
(43) Pub. Date: Apr. 8, 2010

(54) ISOLATION LAYER OF SEMICONDUCTOR DEVICE AND MANUFACTURING METHOD THEREOF

(76) Inventor: Jong-Doo Kim, Eumseong-gun (KR)

Correspondence Address: SHERR & VAUGHN, PLLC, 620 HERNDON PARKWAY, SUITE 320, HERNDON, VA, 20170, US

(21) Appl. No.: 12/565,907

(22) Filed: Sep. 24, 2009

(30) Foreign Application Priority Data
Oct. 6, 2008 (KR) 10-2008-0097657

(51) Int. Cl. H01L 29/06; H01L 21/762; H01L 21/308

(52) U.S. Cl. 257/506; 438/424; 156/345.3; 257/E29.02; 257/E21.546

(57) ABSTRACT

A device isolation layer includes a semiconductor substrate defining an upper trench etched to a predetermined depth, a lower trench defined in the semiconductor substrate at a lower part of the upper trench, the lower trench having a smaller width than the upper trench, and an insulating oxide embedded in the upper and lower trenches. Accordingly, since a stepped structure is formed in the trenches, generation voids may be restrained while improving the gap-filling efficiency.

The present application claims priority under 35 U.S.C. 119 to Korean Patent Application No. 10-2008-0097657 (filed on Oct. 16, 2008), which is hereby incorporated by reference in its entirety.

### BACKGROUND

In general, a semiconductor device mounted on a silicon substrate may be divided into device isolation regions, which electrically isolate circuit patterns from one another, and device regions, which constitute the circuit patterns. Recently, various methods for reducing the sizes of the device isolation regions and the device regions have been suggested in accordance with a trend towards higher integration semiconductor devices. A shallow trench isolation (STI) method may be used for manufacturing the device isolation regions.

Hereinafter, a related method for forming an isolation layer of a semiconductor device will be explained in detail with reference to the accompanying drawings. FIG. 1A to FIG. 1D are sectional views illustrating a related method for forming an isolation layer of a semiconductor device.

Referring to FIG. 1A, an oxide layer 110 and a nitride layer 130 are sequentially vapor-deposited on a semiconductor substrate 100. A photoresist is applied on the whole surface of the nitride layer 130 and then patterned through exposing and developing processes, thereby forming a photoresist pattern. The oxide layer 110 and the nitride layer 130 are etched using the photoresist pattern as an etching mask. Next, the photoresist pattern is removed. As a result, the oxide layer pattern 110 and the nitride pattern 130 are completed as shown in FIG. 1A.

Referring to FIG. 1B, etching is performed using the patterned oxide layer pattern 110 and nitride layer pattern 130 as etching masks, thereby forming a trench 150 having a predetermined depth. In FIG. 1C, the patterned oxide layer pattern 110 and nitride layer pattern 130 used in forming the trench 150 are removed through a washing process. A thermal oxidation layer may be formed at the trench 150 by a thermal oxidation process to protect the substrate.

Next, as shown in FIG. 1D, the whole surface of the thermal oxidation layer including the trench 150 is filled with an insulating material, thereby forming an insulating layer 170. A high density plasma (HDP) oxide may be used for the insulating material forming the insulating layer 170. Here, the width of the trench 150 decreases with increasing depth of the device isolation layer in the semiconductor device. Therefore, a void 190 may occur in the insulating material filling the trench 150.

Furthermore, since an interface is unstable, loss of the insulating layer used for the STI process may occur at a middle part of the insulating layer. In this case, a poly oxide may remain at the lost part of the insulating layer during formation of a gate of the semiconductor device, resulting in compromised reliability of the semiconductor device.

### SUMMARY

Embodiments relate to a semiconductor device, and more particularly, to an isolation layer of a semiconductor device and a manufacturing method for the same. In particular, embodiments relate to a device isolation layer of a semiconductor device and a method for manufacturing the device isolation layer, capable of restraining occurrence of a void and improving the efficiency of gap-filling in the device isolation layer.

Embodiments relate to a device isolation layer of a semiconductor substrate which includes a semiconductor substrate defining an upper trench etched to a predetermined depth, a lower trench defined in the semiconductor substrate at a lower part of the upper trench, the lower trench having a smaller width than the upper trench, and an insulating oxide embedded in the upper and lower trenches.

Embodiments relate to a method for manufacturing a device isolation layer for a semiconductor device which includes forming a photoresist pattern over a semiconductor substrate, forming an upper trench by etching part of the semiconductor substrate using the photoresist pattern as an etching mask, extending the photoresist pattern over a part of an inner wall of the upper trench, forming a lower trench by etching the semiconductor substrate using the photoresist material formed over the inner wall of the upper trench as an etching mask, and embedding an insulating oxide in the upper and lower trenches.

Embodiments relate to an apparatus configured to form a photoresist pattern over a semiconductor substrate, form an upper trench by etching part of the semiconductor substrate using the photoresist pattern as an etching mask, extend the photoresist pattern over a part of an inner wall of the upper trench, form a lower trench by etching the semiconductor substrate using the photoresist material formed over the inner wall of the upper trench as an etching mask, and embed an insulating oxide in the upper and lower trenches.

### DRAWINGS

FIG. 1A to FIG. 1D are sectional views illustrating processes of manufacturing a device isolation layer of a semiconductor device according to the related art.

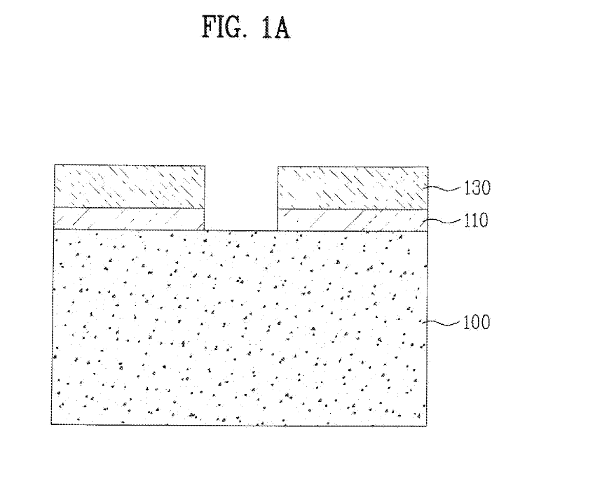

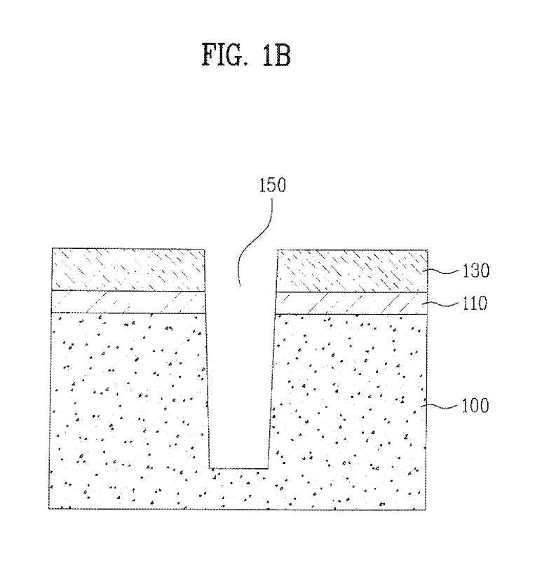

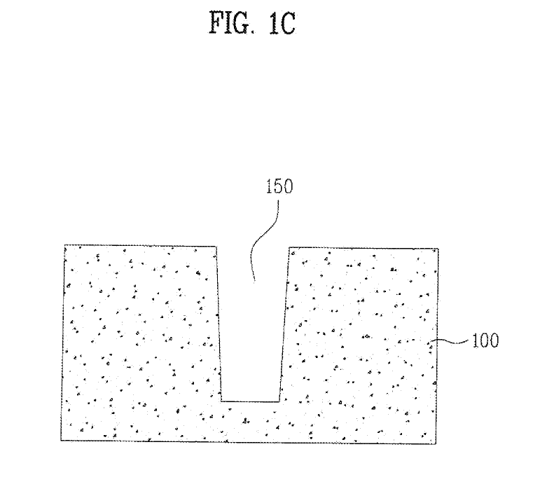

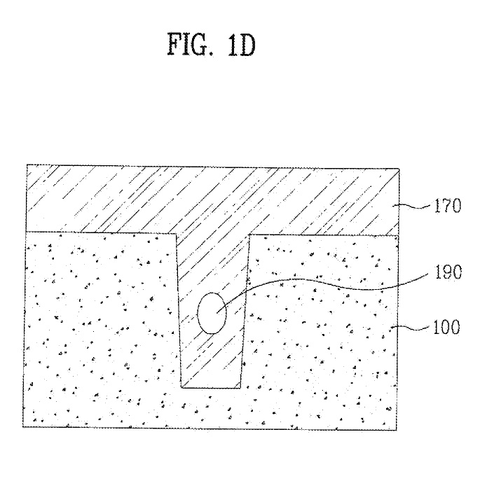

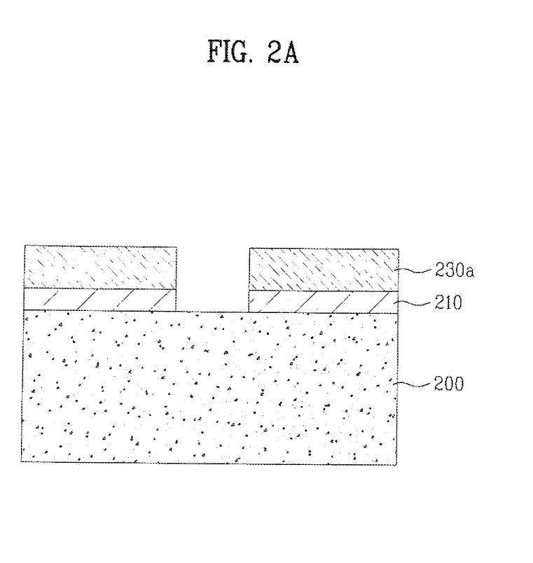

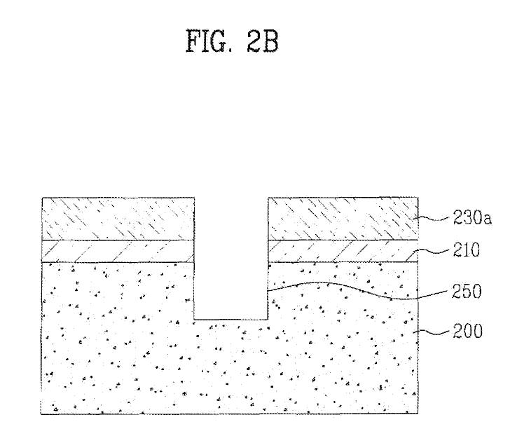

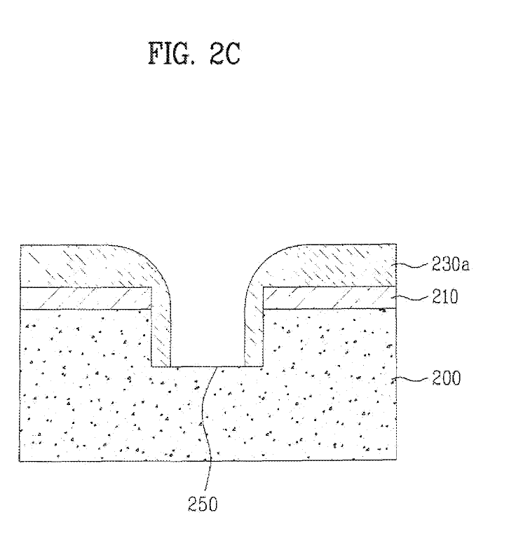

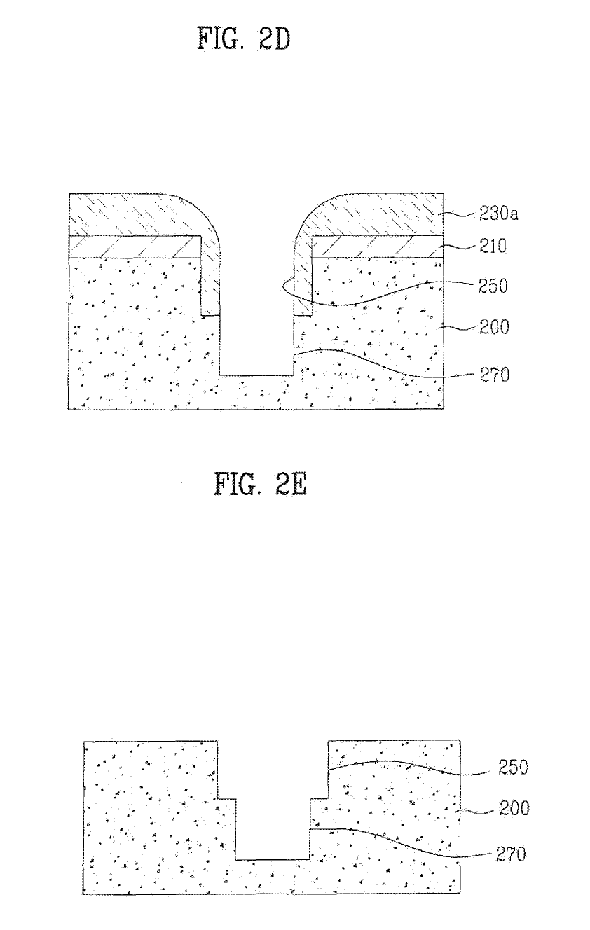

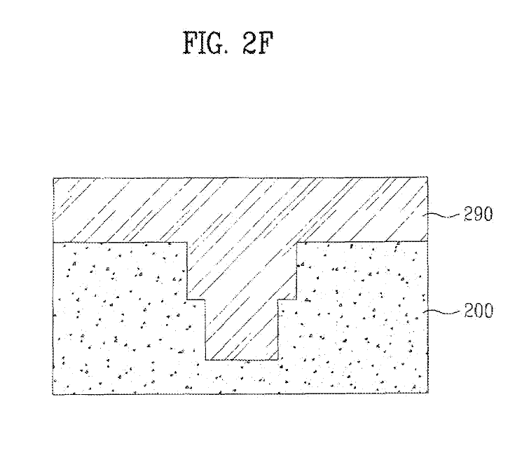

Example FIG. 2A through example FIG. 2F are sectional views illustrating processes of manufacturing a device isolation layer of a semiconductor device according to embodiments.

### DESCRIPTION

Example FIG. 2A through example FIG. 2F are sectional views illustrating processes of manufacturing a device isolation layer of a semiconductor device according to embodiments. First, a reflection prevention layer 210 may be formed over a semiconductor substrate 200 as shown in example FIG. 2A. A photoresist may be applied over the reflection prevention layer 210. Next, the photoresist may be exposed and selectively developed, thereby forming a photoresist pattern 230a as shown in example FIG. 2A.

The photoresist pattern 230a may be cured by exposure. The exposure process uses light with at least a critical energy level with which the photoresist material used for the photoresist pattern 230a can be cured or cross-linked. For example, an electron beam, an ion beam or an extreme ultraviolet (EUV) may be used. Here, light having wavelength L of about 248 nm to 365 nm may be used as the EUV. Next, referring to example FIG. 2A, the reflection prevention layer 210 may be etched using the photoresist pattern 230a as an etching mask.

Referring to FIG. 2B, part of the semiconductor substrate 200 may be etched using the photoresist pattern 230a and the etched reflection prevention layer 210 as etching masks, thereby forming an upper trench 250. Referring to example FIG. 2C, the photoresist pattern 230a may be processed by thermal flow. More specifically, heat may be applied to the photoresist pattern 230a which is cured, so that the material forming the photoresist pattern 230a flows into the upper trench 250. Therefore, the material of the photoresist pattern 230a flowing in the thermal flow process may be partially formed over an inner wall of the upper trench 250. The photoresist material formed over the inner wall of the upper trench 250 may also be exposed and cured.

As shown in example FIG. 2D, a lower part of the upper trench 250 of the semiconductor substrate 200 may be etched using the photoresist pattern 230a and the photoresist 250 over the inner wall of the upper trench 250 as etching masks, accordingly forming a lower trench 270. Here, as the semiconductor substrate 200 is etched using the photoresist flowing to the inner wall of the upper trench 250 as an etching mask, the lower trench 270 may be formed to have a smaller width than the upper trench 250.

Next, as shown in example FIG. 2E, the photoresist pattern 230a may be removed from the semiconductor substrate 200 through ashing or stripping. The reflection prevention layer 210 may also be removed.

Referring to example FIG. 2F, an insulating oxide 290 may be embedded in the upper and lower trenches 250 and 270. An HDP (high density plasma) oxide layer may be used for the insulating oxide 290. In addition, a planarization process may be performed with respect to the whole surface of the semiconductor substrate 200 formed with the embedded insulating oxide 290. The semiconductor substrate 200 may be planarized by chemical mechanical polishing (CMP) and the insulating oxide 290 may be embedded in the upper and lower trenches 250 and 270. Accordingly, an isolation layer may be generated in a manner that the upper and lower trenches 250 and 270 are gap-filled with the insulating oxide 290.

As shown in example FIG. 2F, the isolation layer of the semiconductor device according to embodiments includes the trenches 250 and 270, formed to predetermined depths in a device isolation region of the semiconductor substrate 200 which is divided into the device isolation region and a device region, and the insulating oxide 290 gap-filling the trenches 250 and 270.

Here, the trenches 250 and 270 have different widths. That is, the upper and lower trenches 250 and 270 have a stepped structure since a width B of the lower trench 270 is smaller than a width A of the upper trench 250. Accordingly, the insulating oxide 290 embedded in the upper and lower trenches 250 and 270 has a stepped form.

Thus, the device isolation layer described above not only performs its own function of isolating devices but also partially reduces the width-to-depth ratio of the upper and lower trenches 250 and 270, by virtue of the stepped form between the upper and lower trenches 250 and 270, thereby minimizing voids.

As described above, in an isolation layer of a semiconductor device and a manufacturing method for the same in accordance with embodiments, margins of an insulating layer formed in a trench can be secured although the depth of the trench formed in the semiconductor substrate deepens or narrows. In addition, since the width-to-depth ratio of the trench is partially reduced compared to the related art, with conserving the role of isolation, voids may be prevented.

That is, the isolation layer and the manufacturing method thereof according to embodiments are capable of minimizing voids and improving the gap-filling efficiency by forming a stepped structure in the trench.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate defining an upper trench etched to a predetermined depth;
a lower trench defined in the semiconductor substrate at a lower part of the upper trench, the lower trench having a smaller width than the upper trench; and
an insulating oxide embedded in the upper and lower trenches.

2. The apparatus of claim 1, wherein the insulating oxide isolates circuits within a semiconductor device.

3. The apparatus of claim 1, wherein the insulating oxide embedded in the upper and lower trenches has a stepped form.

4. A method comprising:
forming a photoresist pattern over a semiconductor substrate;
forming an upper trench by etching part of the semiconductor substrate using the photoresist pattern as an etching mask;
extending the photoresist pattern over a part of an inner wall of the upper trench;
forming a lower trench by etching the semiconductor substrate using the photoresist material formed over the inner wall of the upper trench as an etching mask; and
embedding an insulating oxide in the upper and lower trenches.

5. The method of claim 4, including forming the lower trench with a smaller width than the upper trench.

6. The method of claim 4, wherein extending the photoresist pattern includes melting the photoresist pattern in a thermal flow process, and flowing the photoresist over a part of the inner wall of the upper trench.

7. The method of claim 6, wherein the thermal flow process is performed at a higher temperature than a temperature for curing the photoresist pattern.

8. The method of claim 4, wherein the insulating oxide is formed by gap-filling the upper and lower trenches.

9. The method of claim 4, including performing planarization on the insulating oxide formed in the upper and lower trenches.

10. The method of claim 9, wherein performing planarization on the insulating oxide formed in the upper and lower trenches includes performing a chemical mechanical polishing process.

11. The method of claim 4, including:
forming a reflection prevention layer over an upper part of the semiconductor substrate before formation of the photoresist pattern.

12. The method of claim 4, including incorporating the insulating oxide as a device isolation layer of a semiconductor device.

13. The method of claim 4, wherein embedding the insulating oxide includes forming an oxide layer using a high density plasma process.

14. The method of claim 4, wherein forming a photoresist pattern over a semiconductor substrate includes curing the photoresist using ultraviolet light.

15. An apparatus configured to:
form a photoresist pattern over a semiconductor substrate;
form an upper trench by etching part of the semiconductor substrate using the photoresist pattern as an etching mask;
extend the photoresist pattern over a part of an inner wall of the upper trench;
form a lower trench by etching the semiconductor substrate using the photoresist material formed over the inner wall of the upper trench as an etching mask; and
embed an insulating oxide in the upper and lower trenches.

16. The apparatus of claim 15, configured to form the lower trench with a smaller width than the upper trench.

17. The apparatus of claim 15, configured to extend the photoresist pattern by melting the photoresist pattern in a thermal flow process, and flowing the photoresist over a part of the inner wall of the upper trench.

18. The apparatus of claim 17, configured to the thermal flow process is performed at a higher temperature than a temperature for curing the photoresist pattern.

19. The apparatus of claim 15, configured to form the insulating oxide by gap-filling the upper and lower trenches.

20. The apparatus of claim 15, configured to perform planarization on the insulating oxide formed in the upper and lower trenches.
